(19) United States
(12) Patent Application Publication
(10) Pub. No.: US 2012/0244468 A1
(43) Pub. Date: Sep. 27, 2012

(54) POLYVINYL ACETAL/POLYESTER GRAFT COPOLYMER, AND DISPERSANT

(76) Inventors: Chiho Asai, Kyoto-shi (JP); Masayuki Hashimoto, Kyoto-shi (JP); Naofumi Saiuchi, Kyoto-shi (JP)

(21) Appl. No.: 13/513,638

(22) PCT Filed: Oct. 27, 2010
(86) PCT No.: PCT/JP2010/006350

§ 371 Date: Jun. 4, 2012

(30) Foreign Application Priority Data
Dec. 4, 2009 (JP) 2009-276161
Feb. 4, 2010 (JP) 2010-023018
Feb. 16, 2010 (JP) 2010-031199
Jul. 27, 2010 (JP) 2010-167937

(51) Int. Cl. C09D 151/08; C09D 11/16; C09D 11/10; G03G 9/13; G03F 7/004

(52) U.S. Cl. 430/116; 430/270.1; 524/502

(57) ABSTRACT

A polyvinyl acetal/polyester graft copolymer obtained from a polyvinyl acetal having one or more of each of constituent units represented by the following general formulae (1) to (3) (wherein each of R¹ and R² represents a hydrogen atom, a linear or branched alkyl group having a carbon number of from 1 to 20, or an aryl group, in which the alkyl group or the aryl group may have a substituent) and having a weight average molecular weight of from 100 to 100,000 is used as a dispersant which prevents aggregation of solid particles in a dispersion liquid from occurring, is effective for forming a stable dispersion liquid, and exhibits excellent heat resistance.

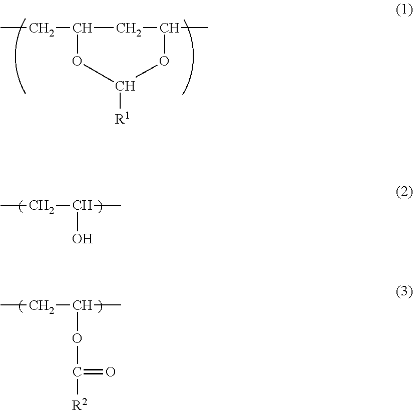

### TECHNICAL FIELD

The present invention relates to a polyvinyl acetal/polyester graft copolymer, and a dispersant and a dispersion each using the same.

### BACKGROUND ART

Technologies for dispersing solid particles in a nonaqueous liquid are utilized in various industrial fields. Dispersion of a pigment in the field of, for example, paints, printing inks, toners for electrostatic copying, plastics, pigment printing agents, inks for inkjet printing, inks for thermal transfer recording, resists for color filter, inks for writing, etc. is an important basic technology. In producing such a dispersion composition, there is involved such a problem that solid particles are easily aggregated. It is known that when aggregation occurs, undesirable phenomena such as a lowering of stability, a lowering of luster, tinting strength or gloss of a final product, ramification, etc. are caused. In consequence, for the purposes of preventing such aggregation from occurring and enhancing dispersibility, a dispersant is used.

As conventional nonaqueous dispersants, for example, reaction products between a polyester and a polyamine, and the like are known (Patent Documents 1 to 3). Specifically, reaction products between a hydroxystearic acid condensate and polyethyleneimine, reaction products between a polycaprolactone based polyester compound and polyallylamine, and the like are disclosed.

The majority of those dispersants have a polyamine as an anchoring group. However, if the dispersant has an amine skeleton, there was encountered such a problem that yellowing is caused at high temperatures.

In order to solve this problem, dispersants not having an amine skeleton are investigated. However, thoroughly satisfactory performances have not been revealed yet.

On the contrary, the present inventors found that a copolymer containing a polyvinyl acetal has a dispersion performance in a certain case. Patent Document 4 discloses a method for producing a lactone-modified polyvinyl acetal resin by subjecting a polyvinyl acetal to addition polymerization with a lactone monomer. However, an application as a dispersant is not described at all.

### RELATED DOCUMENTS

### Patent Documents

Patent Document 1: JP-A-9-176511
Patent Document 2: JP-A-7-207012
Patent Document 3: JP-A-9-169821
Patent Document 4: JP-A-8-100024

### OUTLINE OF THE INVENTION

### Problems to be Solved by the Invention

In view of the foregoing circumstances, the invention has been made, and its object is to provide a dispersant which in dispersing solid particles in various nonaqueous liquids, prevents aggregation of the solid particles in a dispersion liquid from occurring, is extremely effective for forming a stable dispersion liquid, and exhibits excellent heat resistance.

### Means for Solving the Problems

The polyvinyl acetal/polyester graft copolymer of the invention is one obtained by allowing a polyvinyl acetal having one or more of each of constituent units represented by the following general formulae (1) to (3) and having a weight average molecular weight of from 100 to 100,000 and a polyester having at least one carboxyl group at an end of a main chain thereof and having a weight average molecular weight of from 100 to 50,000 to react with each other, wherein from 1 to 95% by mole of a hydroxyl group which the polyvinyl acetal has forms a graft bond with the polyester.

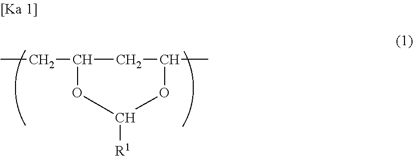

Here, R¹ represents a hydrogen atom, a linear or branched alkyl group having a carbon number of from 1 to 20, or an aryl group, in which the alkyl group or the aryl group may have a substituent.

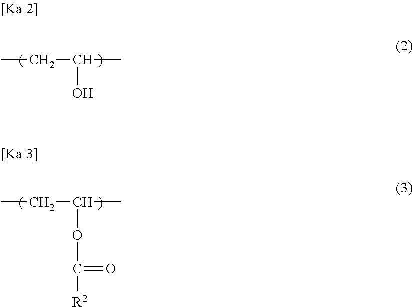

Here, R² represents a hydrogen atom, a linear or branched alkyl group having a carbon number of from 1 to 20, or an aryl group, in which the alkyl group or the aryl group may have a substituent.

Alternatively, the polyvinyl acetal/polyester graft copolymer of the invention is one obtained by subjecting a polyvinyl acetal having one or more of each of constituent units represented by the foregoing general formulae (1) to (3) and having a weight average molecular weight of from 100 to 100,000 to addition polymerization with a lactone in an amount of from 1 to 50 molar equivalents to a hydroxyl group which this polyvinyl acetal has.

In still another embodiment, the polyvinyl acetal/polyester graft copolymer of the invention is one obtained by allowing a polyvinyl acetal having one or more of each of constituent units represented by the foregoing general formulae (1) to (3) and having a weight average molecular weight of from 100 to 100,000 and a polyester having a weight average molecular weight of from 100 to 50,000 to react with each other, wherein from 1 to 95% by mole of a hydroxyl group which the polyvinyl acetal has forms a bond by an ester exchange reaction with the polyester.

The dispersant of the invention is one containing any one of the foregoing polyvinyl acetal/polyester graft copolymers.

Also, the solid particle dispersion of the invention is one obtained by dispersing solid particles in a nonaqueous liquid by the foregoing dispersant of the invention.

### Advantage of the Invention

The polyvinyl acetal/polyester graft copolymer of the invention becomes a dispersant which in dispersing solid particles in various nonaqueous liquids, prevents aggregation of the solid particles in a dispersion liquid from occurring and is extremely effective for forming a stable dispersion liquid. The present dispersant exhibits excellent dispersibility, fluidity and storage stability and also exhibits excellent compatibility with a dispersion medium. Furthermore, the polyvinyl acetal/polyester graft copolymer of the invention does not have an amine skeleton, and therefore, it also exhibits excellent heat resistance.

### MODE FOR CARRYING OUT THE INVENTION

### 1. Polyvinyl Acetal/Polyester Graft Copolymer by Reaction with Carboxyl Group-Terminated Polyester

The polyvinyl acetal/polyester graft copolymer of the invention is a reaction product between a polyvinyl acetal and a polyester having at least one carboxyl group, wherein from 1 to 95% by mole of a hydroxyl group which the polyvinyl acetal has forms a graft bond with the polyester.

The polyvinyl acetal has the constituent units represented by the foregoing general formulae (1) to (3) and is obtained by acetalization of polyvinyl alcohol with an aldehyde. Examples of the aldehyde to be used include formaldehyde, acetaldehyde, propanal, butanal, isobutanal, pentanal, hexanal, heptanal, octanal, nonanal, isononanal, decanal, benzaldehyde, and mixtures thereof.

A weight average molecular weight of the polyvinyl acetal which is used in the invention is from 100 to 100,000, and preferably from 1,000 to 50,000. When the weight average molecular weight is less than 100, a lowering of performance, such as a lowering of dispersibility, etc., is observed, whereas when it is more than 100,000, the viscosity at the time of use as a dispersant is high so that handling becomes difficult.

The carboxyl group-terminated polyester is obtained by allowing a hydroxycarboxylic acid and/or a polycondensate thereof and a lactone compound represented by the following general formula (4) to react with each other.

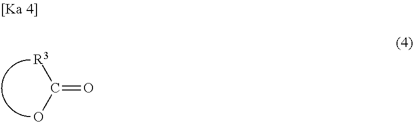

Here, R³ represents a linear or branched alkylene group having a carbon number of from 2 to 20, and the alkylene group may have a substituent.

As the hydroxycarboxylic acid, aliphatic or aromatic, unsaturated hydroxycarboxylic acids can be used. Examples thereof include ricinoleic acid, ricinolic acid, 12-hydroxystearic acid, castor oil fatty acid, hydrogenated castor oil, 8-hydroxyvaleric acid, lactic acid, glycolic acid, hydroxyisophthalic acid, hydroxypivalic acid, 4-hydroxyisophthalic acid, salicylic acid, 11-oxy-hexadodecanoic acid, 2-oxydodecanoic acid, 2,2-dimethylolpropionic acid, 2,2-dimethylolbutyric acid, 2,2-dimethylolvaleric acid, 2,2-dimethylolpentanoic acid, malic acid, tartaric acid, gluconic acid, 4,4-bis(hydroxyphenyl)butyric acid, glucronic acid, 3-hydroxybutanoic acid, and mixtures thereof.

Examples of the lactone compound include ε-caprolactone, δ-valerolactone, β-methyl-δ-valerolactone, β-propiolactone, γ-butyrolactone, 2-methylcaprolactone, 4-methylcaprolactone, nonalactone, and mixtures thereof.

A reaction ratio of the hydroxycarboxylic acid to the lactone compound is in the range of from 1/1 to 1/100, and preferably from 1/5 to 1/50 in terms of a molar ratio.

A weight average molecular weight of the polyester which is used in the invention is in the range of from 100 to 50,000, and preferably from 1,000 to 10,000. When the weight average molecular weight is less than 100, a lowering of performance, such as a lowering of dispersibility, etc., is observed, whereas when it is more than 50,000, the viscosity at the time of use as a dispersant is high so that handling becomes difficult.

The synthesis of a polyester from the foregoing hydroxycarboxylic acid and/or condensate thereof and the lactone compound can be carried out at a temperature in the range of from 100° C. to 220° C., and preferably from 140° C. to 210° C. On that occasion, as an esterification catalyst, organic tin compounds such as tin octylate, dibutyltin oxide, dibutyltin laurate, monobutyltin hydroxybutyl oxide, dioctyltin neodecanate, etc.; tin compounds such as stannous oxide, stannous chloride, etc.; titanium compounds such as tetrabutyl titanate, tetraethyl titanate, tetrapropyl titanate, etc.; and other known esterification catalysts can be utilized. A use amount of the catalyst is from 0.1 ppm to 1,000 ppm, and preferably from 1 ppm to 100 ppm. Also, in order to prevent coloration from occurring, the reaction is preferably carried out in an insert gas atmosphere such as nitrogen, etc.

The polyvinyl acetal/polyester graft copolymer of the invention is obtained due to the matter that when the polyvinyl acetal and the carboxyl group-terminated polyester are allowed to react with each other, the hydroxyl group which the polyvinyl acetal has and the terminal carboxyl group which the polyester has form a graft bond. The hydroxyl group which the polyvinyl acetal has forms a graft bond in an amount in the range of from 1 to 95% by mole with the polyester. Preferably, from 4 to 50% by mole of this hydroxyl group forms a graft bond with the polyester.

A rate of reaction of the carboxyl group-containing polyester relative to the polyvinyl acetal is preferably from 20 to 100% by weight, and the unreacted polyester may remain.

Taking the use of the polyvinyl acetal/polyester graft copolymer of the invention as a dispersant into consideration, a weight average molecular weight thereof is preferably from 5,000 to 500,000.

### 2. Polyvinyl Acetal/Polyester Graft Copolymer by Addition Polymerization with Lactone

The second polyvinyl acetal/polyester graft copolymer of the invention is a polyvinyl acetal/polylactone graft copolymer obtained by subjecting a polyvinyl acetal having a weight average molecular weight of from 100 to 100,000 to addition polymerization with a lactone in an amount of from 1 to 50 molar equivalents to a hydroxyl group which this polyvinyl acetal has.

As described above, the polyvinyl acetal which is used in the invention has one or more of the constituent units represented by the general formulae (1) to (3) and is obtained by acetalization of polyvinyl alcohol with an aldehyde.

Next, examples of the lactone compound which is used in the invention include ε-caprolactone, δ-valerolactone, β-methyl-δ-valerolactone, β-propiolactone, γ-butyrolactone, 2-methylcaprolactone, 4-methylcaprolactone, nonalactone, and mixtures thereof.

As for a reaction ratio of the polyvinyl acetal and the lactone compound, a proportion of the lactone compound is in the range of from 1 to 50 molar equivalents, and preferably from 1 to 20 molar equivalents per mole of the hydroxyl group of the polyvinyl acetal. When the proportion of the lactone compound is less than 1 molar equivalent, a desirable dispersion performance is not obtained, whereas when it is more than 50 molar equivalents, the viscosity at the time of use as a dispersant is high so that handling becomes difficult.

The reaction between the polyvinyl acetal and the lactone compound can be carried out at a temperature in the range of from 100° C. to 220° C., and preferably from 140° C. to 210° C. On that occasion, as an esterification catalyst, organic tin compounds such as tin octylate, dibutyltin oxide, dibutyltin laurate, monobutyltin hydroxybutyl oxide, dioctyltin neodecanate, etc.; tin compounds such as stannous oxide, stannous chloride, etc.; titanium compounds such as tetrabutyl titanate, tetraethyl titanate, tetrapropyl titanate, etc.; and other known esterification catalysts can be utilized. A use amount of the catalyst is usually in the range of from 0.001 to 1 part by weight, and preferably from 0.01 to 0.5 parts by weight based on 100 parts by weight of a total sum of the polyvinyl acetal and the lactone compound. Also, in order to prevent coloration from occurring, the reaction is preferably carried out in an insert gas atmosphere such as nitrogen, etc.

Taking the use of the polyvinyl acetal/polyester graft copolymer of the invention as a dispersant into consideration, a weight average molecular weight thereof is preferably in the range of from 1,000 to 5,000,000, and more preferably from 10,000 to 1,000,000.

### 3. Polyvinyl Acetal/Polyester Graft Copolymer by Ester Exchange Reaction with Polyester

The polyvinyl acetal/polyester graft copolymer of the invention is a reaction product between a polyvinyl acetal and a polyester and is one in which from 1 to 95% by mole of a hydroxyl group which the polyvinyl acetal has forms a bond by an ester exchange reaction with the polyester.

As described above, the polyvinyl acetal which is used in the invention has the constituent units represented by the general formulae (1) to (3) and is obtained by acetalization of polyvinyl alcohol with an aldehyde.

The polyester which is used in the invention is obtained by a ring-opening polymerization reaction of a lactone compound, a polycondensation reaction between a polyvalent carboxylic acid and a polyhydric alcohol, a polycondensation reaction of a hydroxycarboxylic acid, or the like.

Examples of the lactone compound include ε-caprolactone, δ-valerolactone, β-methyl-δ-valerolactone, β-propiolactone, γ-butyrolactone, 2-methylcaprolactone, 4-methylcaprolactone, nonalactone, and mixtures thereof.

The ring-opening polymerization reaction of the lactone compound can be carried out by known methods. For example, the lactone compound can be subjected to ring-opening polymerization by using an alcohol or amine-containing compound as an initiator.

As the alcohol which is used for the initiator, aliphatic monoalcohols such as methanol, ethanol, 1-propanol, isopropanol, 1-butanol, isobutanol, tert-butanol, 1-pentanol, isopentanol, 1-hexanol, cyclohexanol, 4-methylpentanol, 1-heptanol, 1-octanol, isooctanol, 2-ethylhexanol, 1-nonanol, isononanol, 1-decanol, 1-dodecanol, 1-myristyl alcohol, cetyl alcohol, 1-stearyl alcohol, isostearyl alcohol, oleyl alcohol, 2-octyl decanol, 2-octyl dodecanol, 2-hexyl decanol, behenyl alcohol, etc.; aromatic monoalcohols such as benzyl alcohol, phenylethyl alcohol, etc.; hydroxyl group-containing (meth)acrylic acid esters such as 2-hydroxyethyl acrylate, 2-hydroxyethyl methacrylate, etc.; alkylene glycol monoalkyl ethers such as ethylene glycol monomethyl ether, ethylene glycol monoethyl ether, ethylene glycol monopropyl ether, ethylene glycol monobutyl ether, ethylene glycol monohexyl ether, ethylene glycol mono-2-ethylhexyl ether, propylene glycol monomethyl ether, propylene glycol monoethyl ether, propylene glycol monopropyl ether, propylene glycol monobutyl ether, propylene glycol monohexyl ether, propylene glycol mono-2-ethylhexyl ether, diethylene glycol monomethyl ether, diethylene glycol monoethyl ether, diethylene glycol monopropyl ether, diethylene glycol monobutyl ether, diethylene glycol monohexyl ether, diethylene glycol mono-2-ethylhexyl ether, dipropylene glycol monomethyl ether, dipropylene glycol monoethyl ether, dipropylene glycol monopropyl ether, dipropylene glycol monobutyl ether, dipropylene glycol monohexyl ether, dipropylene glycol mono-2-ethylhexyl ether, triethylene glycol monomethyl ether, triethylene glycol monoethyl ether, triethylene glycol monopropyl ether, triethylene glycol monobutyl ether, triethylene glycol monohexyl ether, triethylene glycol mono-2-ethylhexyl ether, tripropylene glycol monomethyl ether, tripropylene glycol monoethyl ether, tripropylene glycol monopropyl ether, tripropylene glycol monobutyl ether, tripropylene glycol monohexyl ether, tripropylene glycol mono-2-ethylhexyl ether, tetraethylene glycol monomethyl ether, tetraethylene glycol monoethyl ether, tetraethylene glycol monopropyl ether, tetraethylene glycol monobutyl ether, tetraethylene glycol monohexyl ether, tetraethylene glycol mono-2-ethylhexyl ether, tetrapropylene glycol monomethyl ether, tetrapropylene glycol monoethyl ether, tetrapropylene glycol monopropyl ether, tetrapropylene glycol monobutyl ether, tetrapropylene glycol monohexyl ether, tetrapropylene glycol mono-2-ethylhexyl ether, tetradiethylene glycol monomethyl ether, etc.; dihydric alcohols such as ethylene glycol, 1,2-propylene glycol, 1,3-propylene glycol, 1,2-butanediol, 1,3-butanediol, 1,4-butanediol, 2-methyl-1,3-propanediol, 1,6-hexanediol, 1,10-decanediol, diethylene glycol, triethylene glycol, tetraethylene glycol, pentaethylene glycol, dipropylene glycol, tripropylene glycol, tetrapropylene glycol, 1,4-cyclohexanedimethanol, 1,4-benzenedimethanol, 2,2-bis-(4-hydroxyethoxyphenyl)propane, 1,4-bis(2-hydroxyethyl)benzene, 1,6-bis(2-hydroxyethoxy)hexane, etc.; and polyhydric alcohols such as butanediol, neopentyl glycol, 1,4-hexanediol, glycerin, trimethylolethane, trimethylolpropane, tris(2-hydroxyethyl)isocyanurate, pentaerythritol, ditrimethylolpropane, dipentaerythritol, mannitol, sorbitol, etc. can be used.

Examples of the amine which is used for the initiator include methylamine, dimethylamine, ethylamine, diethylamine, triethylamine, methylethylamine, propylamine, dipropylamine, cyclohexylamine, phenylamine, benzylamine, pyrrolidine, morpholine, methylenediamine, ethylenediamine, tetraethylenediamine, hexaethylenediamine, propylenediamine, diphenyldiaminomethane, p-phenylenediamine, hexamethylenediamine, isophorone diamine, ethanolamine, diethylenetriamine, diethylaminopropylamine, piperazine, triethylenetetramine, and so on.

The ring-opening polymerization reaction of the lactone compound is advanced by adding the initiator and a catalyst to the lactone compound and heating. A reaction temperature is usually in the range of from 100° C. to 220° C., and preferably from 140° C. to 210° C. As the catalyst, organic tin compounds such as tin octylate, dibutyltin oxide, dibutyltin laurate, monobutyltin hydroxybutyl oxide, dioctyltin neodecanate, etc.; tin compounds such as stannous oxide, stannous chloride, etc.; titanium compounds such as tetrabutyl titanate, tetraethyl titanate, tetrapropyl titanate, etc.; and other known esterification catalysts can be utilized. A use amount of the catalyst is preferably from 0.1 ppm to 1,000 ppm, and more preferably from 1 ppm to 100 ppm. Also, in order to prevent coloration from occurring, the reaction is preferably carried out in an insert gas atmosphere such as nitrogen, etc.

As a ring-opening polymerization product of the lactone compound, a commercially available polylactone polyol may also be used. For example, “PLACCEL” Series, manufactured by Daicel Corporation can be used.

The polyester which is used in the invention can also be obtained by a polycondensation reaction between a polyvalent carboxylic acid and a polyhydric alcohol.

Examples of the polyvalent carboxylic acid include phthalic acid, isophthalic acid, terephthalic acid, 2,6-naphthalenedicarboxylic acid, succinic acid, glutaric acid, adipic acid, sebacic acid, maleic acid, fumaric acid, tetrahydrophthalic acid, hexahydrophthalic acid, trimellitic acid, pyromellitic acid, and so on.

Examples of the polyhydric alcohol include ethylene glycol, 1,2-propylene glycol, 1,3-propylene glycol, 1,2-butanediol, 1,3-butanediol, 1,4-butanediol, 2-methyl-1,3-propanediol, 1,6-hexanediol, 1,10-decanediol, diethylene glycol, triethylene glycol, tetraethylene glycol, pentaethylene glycol, dipropylene glycol, tripropylene glycol, tetrapropylene glycol, 1,4-cyclohexanedimethanol, 1,4-benzenedimethanol, 2,2-bis-(4-hydroxyethoxyphenyl)propane, 1,4-bis(2-hydroxyethyl)benzene, 1,6-bis(2-hydroxyethoxy)hexane, butanediol, neopentyl glycol, 1,4-hexanediol, glycerin, trimethylolethane, trimethylolpropane, tris(2-hydroxyethyl)isocyanurate, pentaerythritol, ditrimethylolpropane, dipentaerythritol, mannitol, sorbitol, and so on.

The polycondensation reaction between the polyvalent carboxylic acid and the polyhydric alcohol can be carried out by adding a catalyst and heating. A reaction temperature is in the range of from 100° C. to 220° C., and preferably from 140° C. to 210° C. As the catalyst, organic tin compounds such as tin octylate, dibutyltin oxide, dibutyltin laurate, monobutyltin hydroxybutyl oxide, dioctyltin neodecanate, etc.; tin compounds such as stannous oxide, stannous chloride, etc.; titanium compounds such as tetrabutyl titanate, tetraethyl titanate, tetrapropyl titanate, etc.; and other known esterification catalysts can be utilized. A use amount of the catalyst is from 0.1 ppm to 1,000 ppm, and preferably from 1 ppm to 100 ppm. Also, in order to prevent coloration from occurring, the reaction is preferably carried out in an insert gas atmosphere such as nitrogen, etc.

The polyester which is used in the invention can be obtained by a polycondensation reaction of a hydroxycarboxylic acid.

As the hydroxycarboxylic acid, aliphatic or aromatic, unsaturated hydroxycarboxylic acids can be used. Examples thereof include ricinoleic acid, ricinolic acid, 12-hydroxystearic acid, castor oil fatty acid, hydrogenated castor oil, δ-hydroxyvaleric acid, lactic acid, glycolic acid, hydroxyisophthalic acid, hydroxypivalic acid, 4-hydroxyisophthalic acid, salicylic acid, 11-oxy-hexadodecanoic acid, 2-oxydodecanoic acid, 2,2-dimethylolpropionic acid, 2,2-dimethylolbutyric acid, 2,2-dimethylolvaleric acid, 2,2-dimethylolpentanoic acid, malic acid, tartaric acid, gluconic acid, 4,4-bis(hydroxyphenyl)butyric acid, glucronic acid, 3-hydroxybutanoic acid, and mixtures thereof.

The polycondensation reaction of the hydroxycarboxylic acid can be carried out by adding a catalyst and heating. A reaction temperature is in the range of from 100° C. to 220° C., and preferably from 140° C. to 210° C. As the catalyst, organic tin compounds such as tin octylate, dibutyltin oxide, dibutyltin laurate, monobutyltin hydroxybutyl oxide, dioctyltin neodecanate, etc.; tin compounds such as stannous oxide, stannous chloride, etc.; titanium compounds such as tetrabutyl titanate, tetraethyl titanate, tetrapropyl titanate, etc.; and other known esterification catalysts can be utilized. A use amount of the catalyst is preferably from 0.1 ppm to 1,000 ppm, and more preferably from 1 ppm to 100 ppm. Also, in order to prevent coloration from occurring, the reaction is preferably carried out in an insert gas atmosphere such as nitrogen, etc.

A weight average molecular weight of the polyester which is used in the invention is preferably in the range of from 100 to 50,000, and more preferably from 1,000 to 10,000. When the weight average molecular weight is less than 100, a lowering of performance, such as a lowering of dispersibility, etc., is observed, whereas when it is more than 50,000, the viscosity at the time of use as a dispersant is high so that handling becomes difficult.

The polyvinyl acetal/polyester graft copolymer of the invention can be obtained by an ester exchange reaction between the polyvinyl acetal and the polyester.

The ester exchange reaction can be carried out according to a known method. The reaction is carried out usually at a temperature of from 80° C. to 280° C., and preferably from 140° C. to 250° C. and usually for from 0.5 to 12 hours, and preferably 4 to 8 hours, and a catalyst may be used. Examples of the catalyst include organic tin compounds such as tin octylate, dibutyltin oxide, dibutyltin laurate, monobutyltin hydroxybutyl oxide, dioctyltin neodecanate, etc.; tin compounds such as stannous oxide, stannous chloride, etc.; titanium compounds such as tetrabutyl titanate, tetraethyl titanate, tetrapropyl titanate, etc.; protonic acids such as phosphoric acid, boric acid, sulfuric acid, p-toluenesulfonic acid, methanesulfonic acid, etc.; alkali metal compounds such as potassium hydroxide, sodium hydroxide, sodium methoxide, etc.; and so on. Also, in order to prevent coloration from occurring, the reaction is preferably carried out in an insert gas atmosphere such as nitrogen, etc.

In the polyvinyl acetal/polyester graft copolymer of the invention, when the polyvinyl acetal and the polyester are allowed to react with each other, a part of the hydroxyl group which the polyvinyl acetal has undergoes ester exchange with the polyester, thereby forming a graft bond. The hydroxyl group which the polyvinyl acetal has forms a graft bond in an amount in the range of from 1 to 95% by mole with the polyester. Preferably, from 2 to 50% by mole of this hydroxyl group forms a graft bond with the polyester. In all of the cases, the unreacted polyester may remain.

Taking the use of the polyvinyl acetal/polyester graft copolymer of the invention as a dispersant into consideration, a weight average molecular weight thereof is preferably from 5,000 to 500,000.

### 4. Use as Dispersant

The polyvinyl acetal/polyester graft copolymer of the invention can be suitably used as a dispersant and is effective for both inorganic and organic solid particles. Specifically, it enables solid particles to be stably dispersed in a high concentration and a low viscosity in a dispersion medium which is usually used in various fields of paints, printing inks, toners for electrostatic copying, plastics, pigment printing agents, inks for inkjet printing, inks for thermal transfer recording, resists for color filter, inks for writing, etc.

Though the solid particles to be dispersed by the polyvinyl acetal/polyester graft copolymer of the invention are not particularly limited, examples of inorganic particles include kaolin, aluminum silicate, clay, talc, mica, calcium silicate, bentonite, magnesium silicate, asbestos, calcium carbonate, magnesium carbonate, barium carbonate, dolomite, calcium sulfate, barium sulfate, aluminum sulfate, zirconia, magnesia, alumina, antimony trioxide, titanium oxide, diatomaceous earth, iron oxide, zinc oxide, aluminum hydroxide, iron hydroxide, silicon carbide, silicon nitride, boron nitride, barium titanate, carbon black, graphite, an iron powder, a silver powder, an aluminum powder, a copper powder, a nickel powder, a gold powder, and so on. Examples of organic particles include organic pigments such as azo series, diazo series, condensed azo series, thio indigo series, indanthrone series, quinacridone series, anthraquinone series, benzoimidazolone series, perylene series, phthalocyanine series, anthrapyridine series, dioxazine series, etc., starch, a polyethylene resin, a urethane resin, a melamine resin, a polystyrene resin, polylactic acid, solid paraffin, and so on.

Examples of the dispersion medium include aromatic hydrocarbon based solvents such as toluene, xylene, etc.; hydrocarbon based solvents such as n-hexane, cyclohexane, n-heptane, etc.; halogenated hydrocarbon based solvents such as methylene chloride, chloroform, dichloroethane, etc.; ether based solvents such as dioxane, tetrahydrofuran, butyl ether, butyl ethyl ether, diglyme, etc.; ketone based solvents such as methyl isobutyl ketone, cyclohexanone, isophorone, etc.; ester based solvents such as ethyl acetate, butyl acetate, ethylene glycol monoethyl ether acetate, propylene glycol monomethyl ether acetate, etc.; alcohol based solvents such as methyl alcohol, ethyl alcohol, n-propyl alcohol, isopropyl alcohol, n-butyl alcohol, isobutyl alcohol, t-butyl alcohol, amyl alcohol, n-hexyl alcohol, n-heptyl alcohol, 2-ethylhexyl alcohol, lauryl alcohol, stearyl alcohol, cyclopentanol, cyclohexanol, benzyl alcohol, p-t-butyl benzyl alcohol, etc.; and monoether based solvents of an alkylene glycol such as ethylene glycol monomethyl ether, ethylene glycol monoethyl ether, ethylene glycol monobutyl ether, propylene glycol monomethyl ether, propylene glycol monoethyl ether, propylene glycol monobutyl ether, etc.; and besides, amide based solvents such as dimethylacetamide, dimethylformamide, etc. These can be properly used alone or in admixture of two or more kinds thereof.

In the case of using the polyvinyl acetal/polyester graft copolymer of the invention as a dispersant, a use amount thereof is usually from about 1 to 300% by weight relative to the solid particles.

A dispersion method is not particularly limited, and the dispersion can be carried out by a known method using a pulverizer such as a ball mill, a bead mill, a sand mill, etc.

### EXAMPLES

The invention is hereunder specifically described with reference to the Examples, but it should not be construed that the invention is limited to the following Examples. Incidentally, in the following description, the term “parts” expresses “parts by weight”, and the term “%” expresses “% by weight”.

### 1. Examples of Polyvinyl Acetal/Polyether Graft Copolymer Obtained by Reaction with Carboxyl Group-Terminated Polyester

### Production Example 1-1

### Synthesis of Polyester

In a reactor equipped with a nitrogen-introducing tube, a thermometer, and a reflux condenser, 50.0 parts of 12-hydroxystearic acid, 800.0 parts of ε-caprolactone, and 0.1 parts of tetrabutyl titanate were charged, the temperature was elevated to 160° C. in a nitrogen atmosphere over 4 hours, and heating was carried out at 160° C. until the amount of remaining ε-caprolactone reached not more than 1%.

The reaction product was a yellow solid and had a weight average molecular weight of 7,100 and an acid value of 7.9 mgKOH/g.

### Production Example 1-2

### Synthesis of Polyester

In a reactor equipped with a nitrogen-introducing tube, a thermometer, and a reflux condenser, 100.0 parts of 12-hydroxystearic acid, 800.0 parts of ε-caprolactone, and 0.1 parts of tetrabutyl titanate were charged, the temperature was elevated to 160° C. in a nitrogen atmosphere over 4 hours, and heating was carried out at 160° C. until the amount of remaining ε-caprolactone reached not more than 1%.

The reaction product was a yellow solid and had a weight average molecular weight of 3,500 and an acid value of 16.0 mgKOH/g.

### Production Example 1-3

### Synthesis of Polyester

In a reactor equipped with a nitrogen-introducing tube, a thermometer, and a reflux condenser, 100.0 parts of 12-hydroxystearic acid, 400.0 parts of ε-caprolactone, and 0.05 parts of tetrabutyl titanate were charged, the temperature was elevated to 160° C. in a nitrogen atmosphere over 4 hours, and heating was carried out at 160° C. until the amount of remaining ε-caprolactone reached not more than 1%.

The reaction product was a yellow solid and had a weight average molecular weight of 2,300 and an acid value of 24.4 mgKOH/g.

### Production Example 1-4

### Synthesis of Polyester

In a reactor equipped with a nitrogen-introducing tube, a thermometer, and a reflux condenser, 100.0 parts of 2,2-dimethylolpropionic acid, 850.0 parts of ε-caprolactone, and 0.05 parts of tetrabutyl titanate were charged, the temperature was elevated to 160° C. in a nitrogen atmosphere over 4 hours, and heating was carried out at 160° C. until the amount of remaining s-caprolactone reached not more than 1%.

The reaction product was a yellow solid and had a weight average molecular weight of 2,000 and an acid value of 29.5 mgKOH/g.

### Production Example 1-5

### Synthesis of Polyester

In a reactor equipped with a nitrogen-introducing tube, a thermometer, and a reflux condenser, 87.0 parts of a 12-hydroxystearic acid condensate (“PHF-33”, manufactured by Itoh Oil Chemicals Co., Ltd.), 46.0 parts of ε-caprolactone, and 0.05 parts of tetrabutyl titanate were charged, the temperature was elevated to 160° C. in a nitrogen atmosphere over 4 hours, and heating was carried out at 160° C. until the amount of remaining s-caprolactone reached not more than 1%.

The reaction product was a yellow solid and had a weight average molecular weight of 3,000 and an acid value of 18.6 mgKOH/g.

### Production Example 1-6

### Synthesis of Polyvinyl Acetal/Polyester Graft Copolymer

In a reactor equipped with a nitrogen-introducing tube, a thermometer, a reflux condenser, and a water measuring tube, 4.1 parts of polyvinyl acetal (a trade name: “S-LEC BX-L”, manufactured by Sekisui Chemical Co., Ltd.; weight average molecular weight: about 20,000, hydroxyl group: 37±3% by mole, acetyl group: not more than 3% by mole, degree of acetalization: about 61% by mole), 129.0 parts (50% by mole relative to the hydroxyl group) of the polyester of Production Example 1-1, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 95,000, a rate of reaction of 41%, an acid value of 3.3 mgKOH/g, and a rate of hydroxyl group consumption of 21% by mole.

### Production Example 1-7

### Synthesis of Polyvinyl Butyral/Polyester Graft Copolymer

In a reactor equipped with a nitrogen-introducing tube, a thermometer, a reflux condenser, and a water measuring tube, 4.1 parts of polyvinyl butyral (a trade name: “S-LEC BL-1”, manufactured by Sekisui Chemical Co., Ltd.; weight average molecular weight: about 19,000, hydroxyl group: about 36% by mole, acetyl group: not more than 3% by mole, degree of butyralization: about 63±3% by mole), 64.5 parts (50% by mole relative to the hydroxyl group) of the polyester of Production Example 1-2, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 70,000, a rate of reaction of 26%, an acid value of 6.5 mgKOH/g, and a rate of hydroxyl group consumption of 13% by mole.

### Production Example 1-8

### Synthesis of Polyvinyl Acetal/Polyester Graft Copolymer

In a reactor equipped with a nitrogen-introducing tube, a thermometer, a reflux condenser, and a water measuring tube, 4.1 parts of polyvinyl acetal (a trade name: “S-LEC BX-L”, manufactured by Sekisui Chemical Co., Ltd.; weight average molecular weight: about 20,000, hydroxyl group: 37±3% by mole, acetyl group: not more than 3% by mole, degree of acetalization: about 61% by mole), 64.5 parts (50% by mole relative to the hydroxyl group) of the polyester of Production Example 1-2, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 55,000, a rate of reaction of 50%, an acid value of 5.1 mgKOH/g, and a rate of hydroxyl group consumption of 25% by mole.

### Production Example 1-9

### Synthesis of Polyvinyl Butyral/Polyester Graft Copolymer

In a reactor equipped with a nitrogen-introducing tube, a thermometer, a reflux condenser, and a water measuring tube, 32.6 parts of polyvinyl butyral (a trade name: “S-LEC BL-1”, manufactured by Sekisui Chemical Co., Ltd.; weight average molecular weight: about 19,000, hydroxyl group: about 36% by mole, acetyl group: not more than 3% by mole, degree of butyralization: about 63±3% by mole), 64.5 parts (8% by mole relative to the hydroxyl group) of the polyester of Production Example 1-2, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 55,000, a rate of reaction of 42%, an acid value of 6.1 mgKOH/g, and a rate of hydroxyl group consumption of 3.4% by mole.

### Production Example 1-10

### Synthesis of Polyvinyl Butyral/Polyester Graft Copolymer

In a reactor equipped with a nitrogen-introducing tube, a thermometer, a reflux condenser, and a water measuring tube, 8.2 parts of polyvinyl butyral (a trade name: “S-LEC BL-1”, manufactured by Sekisui Chemical Co., Ltd.; weight average molecular weight: about 19,000, hydroxyl group: about 36% by mole, acetyl group: not more than 3% by mole, degree of butyralization: about 63±3% by mole), 77.9 parts (25% by mole relative to the hydroxyl group) of the polyester of Production Example 1-3, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 45,000, a rate of reaction of 60%, an acid value of 10.1 mgKOH/g, and a rate of hydroxyl group consumption of 15% by mole.

### Production Example 1-11

### Synthesis of Polyvinyl Acetal/Polyester Graft Copolymer

In a reactor equipped with a nitrogen-introducing tube, a thermometer, a reflux condenser, and a water measuring tube, 12.3 parts of polyvinyl acetal (a trade name: “S-LEC BX-L”, manufactured by Sekisui Chemical Co., Ltd.; weight average molecular weight: about 20,000, hydroxyl group: 37±3% by mole, acetyl group: not more than 3% by mole, degree of acetalization: about 61% by mole), 64.2 parts (50% by mole relative to the hydroxyl group) of the polyester of Production Example 1-4, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 50,000, a rate of reaction of 61%, an acid value of 11.8 mgKOH/g, and a rate of hydroxyl group consumption of 30.5% by mole.

### Production Example 1-12

### Synthesis of Polyvinyl Butyral/Polyester Graft Copolymer

In a reactor equipped with a nitrogen-introducing tube, a thermometer, a reflux condenser, and a water measuring tube, 14.0 parts of polyvinyl butyral (a trade name: “S-LEC BL-1”, manufactured by Sekisui Chemical Co., Ltd.; weight average molecular weight: about 19,000, hydroxyl group: about 36% by mole, acetyl group: not more than 3% by mole, degree of butyralization: about 63±3% by mole), 61.4 parts (20% by mole relative to the hydroxyl group) of the polyester of Production Example 1-5, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 54,000, a rate of reaction of 25%, an acid value of 15.1 mgKOH/g, and a rate of hydroxyl group consumption of 5.0% by mole.

### Comparative Production Example 1-1

### Synthesis of Polyethyleneimine/Polyester Graft Copolymer

In a reactor equipped with a nitrogen-introducing tube, a thermometer, a reflux condenser, and a water measuring tube, 8.1 parts of polyethyleneimine (a trade name: “LUPASOL PR8515”, weight average molecular weight: 2,000), 91.9 parts of the polyester of Production Example 1-1, and 0.05 parts of tetrabutyl titanate were charged, the temperature was elevated to 200° C. in a nitrogen atmosphere, and heating was carried out for 6 hours.

The reaction product was a brown solid and had an amine value of 45.5 mgKOH/g and an acid value of 1.1 mgKOH/g.

### <Molecular Weight of Polyvinyl Acetal/Polyester Graft Copolymer>

The average molecular weight of the polyvinyl acetal/polyester graft copolymer was measured by means of gel permeation chromatography (GPC) using tetrahydrofuran as a solvent.

### <Measurement of Rate of Hydroxyl Group Consumption>

The rate of hydroxyl group consumption of the polyvinyl acetal/polyester graft copolymer was determined according to the following expression.

Rate of hydroxyl group consumption (%)=(a×b)/100

a: Ratio of charged polyester (% by mole relative to hydroxyl group)

b: Rate of reaction between polyvinyl acetal and polyester (%)

### <Heat Resistance Test>

A heat resistance test of each of the polyvinyl acetal/polyester graft copolymers obtained in the foregoing Production Examples 1-6 to 1-12 and Comparative Production Example 1-1 was carried out in the following manner. Results are shown in Table 1.

### Color Difference:

0.5 mg of the dispersant was dissolved in 20 mL of methylene chloride and mixed with 10 g of a silica gel, and the mixture was dried at room temperature. A half amount of the obtained silica gel was heat treated at 200° C. for one hour, and a color difference before and after the treatment was measured.

### Heat Resistance:

The heat resistance was decided on the basis of the color difference according to the following criteria.

A: The color difference (ΔE) is from 0 to 5.

B: The color difference (ΔE) is more than 5 and less than 10.

C: The color difference (ΔE) is 10 or more.

TABLE 1

| | | Color | Heat |
|---|---|---|---|
| | Dispersant | difference (ΔE) | difference |
| Invention | Production Example 1-6 | 2.9 | A |
| product | Production Example 1-7 | 3.2 | A |
| | Production Example 1-8 | 3.0 | A |
| | Production Example 1-9 | 2.7 | A |
| | Production Example 1-10 | 3.6 | A |
| | Production Example 1-11 | 3.1 | A |
| | Production Example 1-12 | 3.0 | A |
| Comparative | Comparative Production | 16.4 | C |
| product | Example 1-1 | | |
| | Dispersant*¹ | 12.5 | C |
| | Dispersant*² | 13.1 | C |

Incidentally, details of the dispersants which are targets for comparison other than that of Comparative Production Example 1-1 are as follows.
*¹A trade name: “AJISPER PB-822”, manufactured by Ajinomoto Fine-Techno Co., Inc., dispersant for a polymer based pigment; amine value: 17 mgKOH/g, acid value: 14 mgKOH/g
*²A trade name: “S-LEC BL-1”, manufactured by Sekisui Chemical Co., Ltd., polyvinyl butyral; weight average molecular weight: about 19,000, hydroxyl group: about 36% by mole, acetyl group: not more than 3% by mole, degree of butyralization: about 63 ± 3% by mole

### <Dispersibility Test>

Each of the polyvinyl acetal/polyester graft polymers obtained in the foregoing Production Examples and the dispersants as targets for comparison was dissolved in a dispersion medium shown in Table 2, to which were then added solid particles shown in Table 2, and the mixture was stirred in a ball mill for 24 hours, thereby preparing a solid particle dispersion. Dispersibility at the time of completion of stirring was visually observed and evaluated according to the following criteria. Results are shown in Table 2.

A: All of the solid particles are dispersed in the liquid, and precipitation does not occur in the bottom at all.

B: Though almost all of the solid particles are dispersed in the liquid, precipitation slightly occurs in the bottom.

C: About a half of the solid particles precipitate in the liquid.

D: Almost all of the solid particles precipitate in the bottom.

### <Test of Coating Film State>

To 10.0 parts of the dispersion after the dispersibility test, 0.4 parts of an acrylic resin (a trade name: “ACRYPET MD”, manufactured by Mitsubishi Rayon Co., Ltd.) was added and dissolved with stirring. The obtained mixed liquid was subjected to flow coating on a slide glass and dried in an oven at 120° C. for one hour. The obtained coating film was visually observed and evaluated according to the following criteria. Results are shown in Table 2.

A: The obtained coating film is transparent.

B: The obtained coating film is cloudy.

C: The solid particles aggregate, and the obtained coating film is not transparent.

TABLE 2

| | | | | | | | | | Coating |
|---|---|---|---|---|---|---|---|---|---|
| | | Dispersant | | Solid particle | | Solvent | | | film |
| | | Type | Ratio (%) | Type | Ratio (%) | Type | Ratio (%) | Dispersibility | state |
| Example | 1-1 | Production Example 1-6 | 1.2 | Pigment Blue 15:6 | 4.1 | PGMEA | 94.7 | A | A |
| | 1-2 | Production Example 1-7 | 1.2 | Pigment Blue 15:6 | 4.1 | PGMEA | 94.7 | A | A |
| | 1-3 | Production Example 1-8 | 1.2 | Pigment Blue 15:6 | 4.1 | PGMEA | 94.7 | A | A |
| | 1-4 | Production Example 1-9 | 1.2 | Pigment Blue 15:6 | 4.1 | PGMEA | 94.7 | A | A |
| | 1-5 | Production Example 1-10 | 1.2 | Pigment Blue 15:6 | 4.1 | PGMEA | 94.7 | A | A |
| | 1-6 | Production Example 1-11 | 1.2 | Pigment Blue 15:6 | 4.1 | PGMEA | 94.7 | A | A |
| | 1-7 | Production Example 1-12 | 1.2 | Pigment Blue 15:6 | 4.1 | PGMEA | 94.7 | A | A |
| | 1-8 | Production Example 1-6 | 1.2 | Pigment Blue 15:6 | 4.1 | Toluene | 94.7 | A | A |
| | 1-9 | Production Example 1-6 | 1.2 | Pigment Blue 15:6 | 4.1 | Butyl cellosolve | 94.7 | A | A |
| | 1-10 | Production Example 1-6 | 1.2 | Pigment Blue 15:6 | 4.1 | Methyl ethyl | 94.7 | A | A |
| | | | | | | ketone | | | |
| | 1-11 | Production Example 1-6 | 1.2 | Pigment Red 177 | 4.1 | PGMEA | 94.7 | A | A |
| | 1-12 | Production Example 1-6 | 1.2 | Pigment Red 254 | 4.1 | PGMEA | 94.7 | A | A |
| | 1-13 | Production Example 1-6 | 1.2 | Zirconia | 4.1 | PGMEA | 94.7 | A | A |
| | 1-14 | Production Example 1-6 | 1.2 | Magnesium oxide | 4.1 | PGMEA | 94.7 | A | A |
| | 1-15 | Production Example 1-6 | 1.2 | Talc | 4.1 | PGMEA | 94.7 | A | A |
| | 1-16 | Production Example 1-6 | 1.2 | Potassium carbonate | 4.1 | PGMEA | 94.7 | A | A |
| Comparative | 1-1 | Production Example 1-1 | 1.2 | Pigment Blue 15:6 | 4.1 | PGMEA | 94.7 | D | C |
| Example | 1-2 | Comparative Production | 1.2 | Pigment Blue 15:6 | 4.1 | PGMEA | 94.7 | B | B |
| | | Example 1-1 | | | | | | | |
| | 1-3 | Dispersant *¹ | 1.2 | Pigment Blue 15:6 | 4.1 | PGMEA | 94.7 | A | A |
| | 1-4 | Dispersant *² | 1.2 | Pigment Blue 15:6 | 4.1 | PGMEA | 94.7 | C | C |

PGMEA: Propylene glycol monomethyl ether acetate

### 2. Examples of Polyvinyl Acetal/Polyester Graft Copolymer Obtained by Addition Polymerization with Lactone

### Production Example 2-1

In a reactor equipped with a nitrogen-introducing tube, a thermometer, and a reflux condenser, 3.0 parts of polyvinyl butyral (a trade name: “S-LEC BL-1”, manufactured by Sekisui Chemical Co., Ltd.; average molecular weight: about 19,000, hydroxyl group: about 36% by mole, acetyl group: not more than 3% by mole, degree of butyralization: about 63±3% by mole), 114.0 parts of ε-caprolactone (40 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow solid and had an average molecular weight of 815,000.

### Production Example 2-2

In a reactor equipped with a nitrogen-introducing tube, a thermometer, and a reflux condenser, 6.1 parts of polyvinyl butyral (a trade name: “S-LEC BL-1”, manufactured by Sekisui Chemical Co., Ltd.; average molecular weight: about 19,000, hydroxyl group: about 36% by mole, acetyl group: not more than 3% by mole, degree of butyralization: about 63±3% by mole), 114.0 parts of ε-caprolactone (20 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 416,000.

### Production Example 2-3

In a reactor equipped with a nitrogen-introducing tube, a thermometer, and a reflux condenser, 12.2 parts of polyvinyl butyral (a trade name: “S-LEC BL-1”, manufactured by Sekisui Chemical Co., Ltd.; average molecular weight: about 19,000, hydroxyl group: about 36% by mole, acetyl group: not more than 3% by mole, degree of butyralization: about 63±3% by mole), 114.0 parts of ε-caprolactone (10 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 216,000.

### Production Example 2-4

In a reactor equipped with a nitrogen-introducing tube, a thermometer, and a reflux condenser, 12.2 parts of polyvinyl acetal (a trade name: “S-LEC BX-L”, manufactured by Sekisui Chemical Co., Ltd.; average molecular weight: about 20,000, hydroxyl group: 37±3% by mole, acetyl group: not more than 3% by mole, degree of acetalization: about 61% by mole), 114.0 parts of ε-caprolactone (10 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 203,000.

### Production Example 2-5

In a reactor equipped with a nitrogen-introducing tube, a thermometer, and a reflux condenser, 24.4 parts of polyvinyl butyral (a trade name: “S-LEC BL-1”, manufactured by Sekisui Chemical Co., Ltd.; average molecular weight: about 19,000, hydroxyl group: about 36% by mole, acetyl group: not more than 3% by mole, degree of butyralization: about 63±3% by mole), 114.0 parts of ε-caprolactone (5 molar equivalents to the hydroxyl group), and 0.2 parts of dioctyltin neodecanate were charged, and heating was carried out at 180° C. in a nitrogen atmosphere until the amount of remaining s-caprolactone reached not more than 1%.

The reaction product was a pale yellow viscous liquid and had an average molecular weight of 145,000.

### Production Example 2-6

In a reactor equipped with a nitrogen-introducing tube, a thermometer, and a reflux condenser, 24.4 parts of polyvinyl acetal (a trade name: “S-LEC BX-L”, manufactured by Sekisui Chemical Co., Ltd.; average molecular weight: about 20,000, hydroxyl group: 37±3% by mole, acetyl group: not more than 3% by mole, degree of acetalization: about 61% by mole), 114.0 parts of ε-caprolactone (5 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 117,000.

### Production Example 2-7

In a reactor equipped with a nitrogen-introducing tube, a thermometer, and a reflux condenser, 2.4 parts of polyvinyl acetal (average molecular weight: about 5,000, hydroxyl group: 36% by mole, acetyl group: not more than 3% by mole, degree of acetalization: about 63% by mole), 114.0 parts of ε-caprolactone (5 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 35,000.

### Production Example 2-8

In a reactor equipped with a nitrogen-introducing tube, a thermometer, and a reflux condenser, 48.8 parts of polyvinyl butyral (a trade name: “S-LEC BL-1”, manufactured by Sekisui Chemical Co., Ltd.; average molecular weight: about 19,000, hydroxyl group: about 36% by mole, acetyl group: not more than 3% by mole, degree of butyralization: about 63±3% by mole), 114.0 parts of ε-caprolactone (2.5 molar equivalents to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 85,000.

### Production Example 2-9

In a reactor equipped with a nitrogen-introducing tube, a thermometer, and a reflux condenser, 97.6 parts of polyvinyl butyral (a trade name: “S-LEC BL-1”, manufactured by Sekisui Chemical Co., Ltd.; average molecular weight: about 19,000, hydroxyl group: about 36% by mole, acetyl group: not more than 3% by mole, degree of butyralization: about 63±3% by mole), 114.0 parts of ε-caprolactone (1 molar equivalent to the hydroxyl group), and 0.2 parts of dioctyltin neodecanate were charged, and heating was carried out at 180° C. in a nitrogen atmosphere until the amount of remaining ε-caprolactone reached not more than 1%.

The reaction product was a pale yellow viscous liquid and had an average molecular weight of 51,000.

### Comparative Production Example 2-1

In a reactor equipped with a nitrogen-introducing tube, a thermometer, a reflux condenser, and a water measuring tube, 10.0 parts of polyethyleneimine (a trade name: “LUPASOL PR8515”, manufactured by BASF AG; molecular weight: 2,000), 114.0 parts of ε-caprolactone, and 0.2 parts of dioctyltin neodecanate were charged, and heating was carried out at 180° C. in a nitrogen atmosphere until the amount of remaining ε-caprolactone reached not more than 1%.

The reaction product was a brown solid.

The residual amount of ε-caprolactone and the molecular weight of the polyvinyl acetal/polyester graft copolymer in each of the foregoing Production Examples and Comparative Production Example were measured in the following manners.

### <Residual Amount of ε-Caprolactone>

The residual amount of ε-caprolactone was measured by a gas chromatography internal standard method (internal standard substance: diphenyl ether) using dichloromethane as a solvent.

### <Molecular Weight of Polyvinyl Acetal/Polyester Graft Copolymer>

The average molecular weight of the polyvinyl acetal/polyester graft copolymer was measured by means of gel permeation chromatography (GPC) using tetrahydrofuran as a solvent.

### <Heat Resistance Test>

A heat resistance test of each of the polyvinyl acetal/polyester graft copolymers obtained in the foregoing Production Examples 2-1 to 2-9 and Comparative Production Example 2-1 was carried out in the following manner. Results are shown in Table 3.

### Color Difference:

0.5 mg of the dispersant was dissolved in 20 mL of methylene chloride and mixed with 10 g of a silica gel, and the mixture was dried at room temperature. A half amount of the obtained silica gel was heat treated at 200° C. for one hour, and a color difference before and after the treatment was measured.

### Heat Resistance:

The heat resistance was decided according to the following criteria.

A: The color difference (ΔE) is from 0 to 5.

B: The color difference (ΔE) is more than 5 and less than 10.

C: The color difference (ΔE) is 10 or more.

TABLE 3

| | | Color | Heat |
|---|---|---|---|
| | Dispersant | difference (ΔE) | difference |
| Invention | Production Example 2-1 | 1.8 | A |
| product | Production Example 2-2 | 1.6 | A |
| | Production Example 2-3 | 2.3 | A |
| | Production Example 2-4 | 2.1 | A |
| | Production Example 2-5 | 1.9 | A |
| | Production Example 2-6 | 2.5 | A |
| | Production Example 2-7 | 2.7 | A |
| | Production Example 2-8 | 2.5 | A |
| | Production Example 2-9 | 2.2 | A |
| Comparative | Comparative Production | 19.6 | C |
| product | Example 2-1 | | |
| | Dispersant*¹ | 12.5 | C |
| | Dispersant*² | 13.1 | C |

Incidentally, details of the dispersants which are a standard for comparison other than that of Comparative Production Example 2-1 are as follows.
*¹A trade name: “AJISPER PB-822”, manufactured by Ajinomoto Fine-Techno Co., Inc., dispersant for a polymer based pigment; amine value: 17 mgKOH/g, acid value: 14 mgKOH/g,
*²A trade name: “S-LEC BL-1”, manufactured by Sekisui Chemical Co., Ltd. for polyvinyl butyral; average molecular weight: about 19,000, hydroxyl group: about 36% by mole, acetyl group: not more than 3% by mole, degree of butyralization: about 63 ± 3% by mole

### <Dispersibility Test>

Each of the polyvinyl acetal/polyester graft polymers obtained in the foregoing Production Examples 2-1 to 2-9 and Comparative Production Example 2-1 and the dispersants as targets for comparison was dissolved in a dispersion medium, to which were then added 4.3 parts of a fine powder and zirconia beads, and the mixture was stirred in a ball mill for 24 hours. Dispersibility was visually observed and evaluated according to the following criteria. Results are shown in Table 4.

A: All of the powders are dispersed in the liquid, and precipitation does not occur in the bottom at all.

B: Though almost all of the powders are dispersed in the liquid, precipitation slightly occurs in the bottom.

C: About a half of the powders precipitate in the liquid.

D: Almost all of the powders precipitate in the bottom.

### <Test of Coating Film State>

To 10.0 parts of the dispersion after the foregoing dispersibility test, 0.4 parts of an acrylic resin (a trade name: “ACRYPET MD”, manufactured by Mitsubishi Rayon Co., Ltd.) was added and dissolved. The solution was subjected to flow coating on a slide glass and dried in an oven at 120° C. for one hour. The obtained coating film was visually observed and evaluated according to the following criteria. Results are shown in Table 4.

A: The obtained coating film is transparent.

B: The obtained coating film is cloudy.

C: The fine particles aggregate, and the obtained coating film is not transparent.

TABLE 4

| | | Dispersant | | Fine powder | | Solvent | | | |
|---|---|---|---|---|---|---|---|---|---|
| | | | Ratio | | Ratio | | Ratio | | Coating |
| | | Type | (%) | Type | (%) | Type | (%) | Dispersibility | film state |
| Example | 2-1 | Production Example 2-1 | 1.2 | Pigment Blue 15:6 | 4.1 | PGMEA | 94.7 | A | A |
| | 2-2 | Production Example 2-2 | 1.2 | Pigment Blue 15:6 | 4.1 | PGMEA | 94.7 | A | A |
| | 2-3 | Production Example 2-3 | 1.2 | Pigment Blue 15:6 | 4.1 | PGMEA | 94.7 | A | A |
| | 2-4 | Production Example 2-4 | 1.2 | Pigment Blue 15:6 | 4.1 | PGMEA | 94.7 | A | A |
| | 2-5 | Production Example 2-5 | 1.2 | Pigment Blue 15:6 | 4.1 | PGMEA | 94.7 | A | A |
| | 2-6 | Production Example 2-6 | 1.2 | Pigment Blue 15:6 | 4.1 | PGMEA | 94.7 | A | A |
| | 2-7 | Production Example 2-7 | 1.2 | Pigment Blue 15:6 | 4.1 | PGMEA | 94.7 | A | A |
| | 2-8 | Production Example 2-8 | 1.2 | Pigment Blue 15:6 | 4.1 | PGMEA | 94.7 | A | A |
| | 2-9 | Production Example 2-9 | 1.2 | Pigment Blue 15:6 | 4.1 | PGMEA | 94.7 | A | A |
| | 2-10 | Production Example 2-5 | 1.2 | Pigment Blue 15:6 | 4.1 | Toluene | 94.7 | A | A |
| | 2-11 | Production Example 2-5 | 1.2 | Pigment Blue 15:6 | 4.1 | Butyl cellosolve | 94.7 | A | A |
| | 2-12 | Production Example 2-5 | 1.2 | Pigment Blue 15:6 | 4.1 | Methyl ethyl | 94.7 | A | A |
| | | | | | | ketone | | | |
| | 2-13 | Production Example 2-5 | 1.2 | Pigment Red 177 | 4.1 | PGMEA | 94.7 | A | A |
| | 2-14 | Production Example 2-5 | 1.2 | Pigment Red 254 | 4.1 | PGMEA | 94.7 | A | A |
| | 2-15 | Production Example 2-5 | 1.2 | Zirconia | 4.1 | PGMEA | 94.7 | A | B |
| | 2-16 | Production Example 2-5 | 1.2 | Magnesium oxide | 4.1 | PGMEA | 94.7 | A | B |
| | 2-17 | Production Example 2-5 | 1.2 | Talc | 4.1 | PGMEA | 94.7 | A | B |
| | 2-18 | Production Example 2-5 | 1.2 | Potassium carbonate | 4.1 | PGMEA | 94.7 | A | B |
| Comparative | 2-1 | Comparative Production | 1.2 | Pigment Blue 15:6 | 4.1 | PGMEA | 94.7 | C | C |
| Example | | Example 2-1 | | | | | | | |
| | 2-2 | Dispersant *¹ | 1.2 | Pigment Blue 15:6 | 4.1 | PGMEA | 94.7 | A | A |
| | 2-3 | Dispersant *² | 1.2 | Pigment Blue 15:6 | 4.1 | PGMEA | 94.7 | C | C |

PGMEA: Propylene glycol monomethyl ether acetate

### 3. Examples of Polyvinyl Acetal/Polyester Graft Copolymer Obtained by Ester Exchange Reaction with Polyester

### Production Example 3-1

### Synthesis of Polyester

In a reactor equipped with a nitrogen-introducing tube, a thermometer, and a reflux condenser, 10.0 parts of methanol, 800.0 parts of ε-caprolactone, and 0.1 parts of tetrabutyl titanate were charged, the temperature was elevated to 160° C. in a nitrogen atmosphere over 4 hours, and heating was carried out at 160° C. until the amount of remaining ε-caprolactone reached not more than 1%.

The reaction product was a yellow solid and had a weight average molecular weight of 3,100.

### Production Example 3-2

### Synthesis of Polyester

In a reactor equipped with a nitrogen-introducing tube, a thermometer, and a reflux condenser, 50.0 parts of diethylene glycol, 800.0 parts of ε-caprolactone, and 0.1 parts of tetrabutyl titanate were charged, the temperature was elevated to 160° C. in a nitrogen atmosphere over 4 hours, and heating was carried out at 160° C. until the amount of remaining s-caprolactone reached not more than 1%.

The reaction product was a yellow solid and had a weight average molecular weight of 2,000.

### Production Example 3-3

### Synthesis of Polyester

In a reactor equipped with a nitrogen-introducing tube, a thermometer, and a reflux condenser, 10.0 parts of diethylene glycol, 800.0 parts of ε-caprolactone, and 0.1 parts of tetrabutyl titanate were charged, the temperature was elevated to 160° C. in a nitrogen atmosphere over 4 hours, and heating was carried out at 160° C. until the amount of remaining ε-caprolactone reached not more than 1%.

The reaction product was a yellow solid and had a weight average molecular weight of 8,500.

### Production Example 3-4

### Synthesis of Polyester

In a reactor equipped with a nitrogen-introducing tube, a thermometer, and a reflux condenser, 100.0 parts of 2-hydroxyethyl methacrylate, 800.0 parts of ε-caprolactone, and 0.05 parts of tetrabutyl titanate were charged, the temperature was elevated to 160° C. in a nitrogen atmosphere over 4 hours, and heating was carried out at 160° C. until the amount of remaining ε-caprolactone reached not more than 1%.

The reaction product was a yellow solid and had a weight average molecular weight of 1,200.

### Production Example 3-5

### Synthesis of Polyester

In a reactor equipped with a nitrogen-introducing tube, a thermometer, a reflux condenser, and a water separator, 400.0 parts of 1,6-hexanediol, 436.0 parts of adipic acid, and 0.05 parts of tetrabutyl titanate were charged, the temperature was elevated to 160° C. in a nitrogen atmosphere over 4 hours, and heating was carried out at 160° C. until the acid value reached 1 mgKOH/g.

The reaction product was a yellow solid and had a weight average molecular weight of 4,200.

### Production Example 3-6

### Synthesis of Polyester

In a reactor equipped with a nitrogen-introducing tube, a thermometer, a reflux condenser, and a water separator, 800.0 parts of 12-hydroxystearic acid and 0.05 parts of tetrabutyl titanate were charged, the temperature was elevated to 160° C. in a nitrogen atmosphere over 4 hours, and heating was carried out at 160° C. until the acid value reached 31 mgKOH/g.

The reaction product was a yellow solid and had a weight average molecular weight of 1,800.

### Production Example 3-7

### Synthesis of Polyvinyl Acetal/Polyester Graft Copolymer

In a reactor equipped with a nitrogen-introducing tube, a thermometer, and a reflux condenser, 49.7 parts of polyvinyl butyral (a trade name: “S-LEC BL-1”, manufactured by Sekisui Chemical Co., Ltd.; weight average molecular weight: about 19,000, hydroxyl group: about 36% by mole, acetyl group: not more than 3% by mole, degree of butyralization: about 63±3% by mole), 50.3 parts (8% by mole relative to the hydroxyl group) of the polyester of Production Example 2, and 0.05 parts of tetrabutyl titanate were charged, the temperature was elevated to 200° C. in a nitrogen atmosphere, and heating was carried out for 6 hours.

The reaction product was a yellow viscous liquid and had a weight average molecular weight of 67,500 and a rate of introduction of polyester of 65.2%.

### Production Examples 3-8 to 3-25

### Synthesis of Polyvinyl Acetal/Polyester Graft Polymer

Polyvinyl butyral/polyester graft polymers were produced according to blending and reaction conditions shown in the following Table 5 in the same manner as that in Production Example 3-7.

### Comparative Production Example 3-1

### Synthesis of Polyethyleneimine/Polyester Graft Copolymer

In a reactor equipped with a nitrogen-introducing tube, a thermometer, a reflux condenser, and a water measuring tube, 8.1 parts of polyethyleneimine (a trade name: “LUPASOL PR8515”, weight average molecular weight: 2,000), 91.9 parts of the polyester of Production Example 3-1, and 0.05 parts of tetrabutyl titanate were charged, the temperature was elevated to 200° C. in a nitrogen atmosphere, and heating was carried out for 6 hours.

The reaction product was a brown liquid and had an amine value of 45.5 mgKOH/g.

### <Molecular Weight of Polyvinyl Acetal/Polyester Graft Copolymer>

The average molecular weight of the polyvinyl acetal/polyester graft copolymer was measured by means of gel permeation chromatography (GPC) using tetrahydrofuran as a solvent.

### <Measurement of Rate of Introduction of Polyester>

The rate of introduction of polyester of the polyvinyl acetal/polyester graft copolymer was determined from measurement results of GPC according to the following expression.

Rate of introduction of polyester (%)=(a−b)/a×100

a: Area ratio of polyester before the reaction (%)

b: Area ratio of polyester after the reaction (%)

TABLE 5

| | Polyvinyl acetal | | Polyester | | | | | Weight | Rate of |
|---|---|---|---|---|---|---|---|---|---|
| | | Charged | | Charged amount | | Reaction | | average | introduction |
| Production | | amount | | | (% by mole relative | temperature | Reaction | molecular | of polyester |
| Example | Type | (parts) | Type | (Parts) | to hydroxyl group) | (° C.) | time (h) | weight | (%) |
| 3-7 | S-LEC BL-1 | 49.7 | Production Example 3-1 | 50.3 | 4 | 200 | 7 | 67,500 | 65.2 |
| 3-8 | S-LEC BL-1 | 49.7 | Production Example 3-1 | 50.3 | 4 | 140 | 7 | 48,300 | 43.9 |
| 3-9 | S-LEC BL-1 | 49.7 | Production Example 3-1 | 50.3 | 4 | 220 | 7 | 77,500 | 69.1 |
| 3-10 | S-LEC BL-1 | 49.7 | Production Example 3-1 | 50.3 | 4 | 200 | 3 | 34,000 | 31.1 |
| 3-11 | S-LEC BL-1 | 49.7 | Production Example 3-1 | 50.3 | 4 | 200 | 12 | 71,300 | 68.2 |
| 3-12 | S-LEC BL-1 | 16.5 | Production Example 3-1 | 83.5 | 20 | 200 | 7 | 123,100 | 79.1 |
| 3-13 | S-LEC BL-1 | 9.0 | Production Example 3-1 | 91.0 | 40 | 200 | 7 | 191,300 | 58.2 |
| 3-14 | S-LEC BX-L *¹ | 9.0 | Production Example 3-1 | 83.5 | 20 | 200 | 7 | 208,200 | 39.6 |
| 3-15 | S-LEC BL-1 | 43.3 | Production Example 3-2 | 56.7 | 8 | 200 | 7 | 41,800 | 75.6 |
| 3-16 | S-LEC BL-1 | 41.9 | Production Example 3-3 | 58.1 | 2 | 200 | 7 | 46,800 | 82.3 |
| 3-17 | S-LEC BL-1 | 20.3 | Production Example 3-4 | 79.7 | 40 | 200 | 7 | 85,300 | 21.5 |
| 3-18 | S-LEC BL-1 | 26.6 | Production Example 3-5 | 73.4 | 8 | 200 | 7 | 70,500 | 52.1 |
| 3-19 | S-LEC BL-1 | 25.3 | Production Example 3-6 | 74.7 | 20 | 200 | 7 | 74,200 | 32.5 |
| 3-20 | S-LEC BL-1 | 45.8 | Production Example 3-6 | 54.2 | 8 | 200 | 7 | 55,200 | 70.2 |
| 3-21 | S-LEC BL-1 | 3.0 | PLACCEL H1P *² | 97.0 | 40 | 200 | 7 | 597,700 | 41.6 |
| 3-22 | S-LEC BL-1 | 46.8 | PLACCEL H1P | 53.2 | 2 | 200 | 7 | 36,100 | 32.1 |
| 3-23 | S-LEC BL-1 | 43.3 | PLACCEL 240 *³ | 56.7 | 4 | 200 | 7 | 71,500 | 65.2 |
| 3-24 | S-LEC BL-1 | 60.5 | PLACCEL 230 *⁴ | 49.5 | 4 | 200 | 7 | 62,000 | 59.8 |
| 3-25 | S-LEC BX-L *¹ | 23.4 | PLACCEL H1P | 76.6 | 4 | 200 | 7 | 91,700 | 59.1 |

Incidentally, in Table 5, details of the polyvinyl acetal used in Production Example 3-14 and 3-25 and the polyesters used in Production Examples 3-21 to 3-25 are as follows.

*1: A trade name “S-LEC BX-L”, manufactured by Sekisui Chemical Co., Ltd. for polyvinyl acetal; average molecular weight: about 20,000, hydroxyl group: 37±3% by mole, acetyl group: not more than 3% by mole, degree of acetalization: about 61% by mole.
*2: A trade name “PLACCEL H1P”, manufactured by Daicel Corporation, polycaprolactone; molecular weight 10,000
*3: A trade name “PLACCEL 240”, manufactured by Daicel Corporation, polycaprolactone diol; molecular weight 4,000
*4: A trade name “PLACCEL 230”, manufactured by Daicel Corporation, polycaprolactone diol; molecular weight 3,000

### <Heat Resistance Test>

A heat resistance test of each of the polyvinyl acetal/polyester graft copolymers obtained in the foregoing Production Examples 3-7 to 3-25 and the polyethyleneimine/polyester graft copolymer obtained in the foregoing Comparative Production Example 3-1 was carried out in the following manner. Results are shown in Table 6.

### Color Difference:

0.5 mg of the dispersant was dissolved in 20 mL of methylene chloride and mixed with 10 g of a silica gel, and the mixture was dried at room temperature. A half amount of the obtained silica gel was heat treated at 200° C. for one hour, and a color difference before and after the treatment was measured.

### Heat Resistance:

The heat resistance was decided on the basis of the color difference according to the following criteria.

A: The color difference (ΔE) is from 0 to 5.

B: The color difference (ΔE) is more than 5 and less than 10.

C: The color difference (ΔE) is 10 or more.

TABLE 6

| | | Color | Heat |
|---|---|---|---|
| | Dispersant | difference (ΔE) | difference |
| Invention | Production Example 3-7 | 2.9 | A |
| product | Production Example 3-8 | 1.2 | A |
| | Production Example 3-9 | 3.9 | A |
| | Production Example 3-10 | 1.7 | A |
| | Production Example 3-11 | 3.1 | A |
| | Production Example 3-12 | 1.6 | A |
| | Production Example 3-13 | 3.9 | A |
| | Production Example 3-14 | 3.6 | A |
| | Production Example 3-15 | 3.0 | A |
| | Production Example 3-16 | 3.2 | A |
| | Production Example 3-17 | 3.1 | A |
| | Production Example 3-18 | 3.2 | A |
| | Production Example 3-19 | 3.2 | A |
| | Production Example 3-20 | 2.6 | A |
| | Production Example 3-21 | 2.7 | A |
| | Production Example 3-22 | 2.9 | A |
| | Production Example 3-23 | 3.1 | A |
| | Production Example 3-24 | 3.0 | A |
| | Production Example 3-25 | 3.5 | A |
| Comparative | Comparative Production | 16.4 | C |
| product | Example 3-1 | | |
| | Dispersant*¹ | 12.5 | C |
| | Dispersant*² | 13.1 | C |

Incidentally, details of the dispersants which are targets for comparison other than that of Comparative Production Example 3-1 are as follows.
*¹A trade name: “AJISPER PB-822”, manufactured by Ajinomoto Fine-Techno Co., Inc., dispersant for a polymer based pigment; amine value: 17 mgKOH/g, acid value: 14 mgKOH/g
*²A trade name: “S-LEC BL-1”, manufactured by Sekisui Chemical Co., Ltd. for polyvinyl butyral; weight average molecular weight: about 19,000, hydroxyl group: about 36% by mole, acetyl group: not more than 3% by mole, degree of butyralization: about 63 ± 3% by mole

### <Dispersibility Test>

Each of the polyvinyl acetal/polyester graft copolymers obtained in the foregoing Production Examples and the dispersants as targets for comparison was dissolved in a dispersion medium shown in Table 7, to which were then added solid particles shown in Table 7, and the mixture was stirred in a ball mill for 24 hours, thereby preparing a solid particle dispersion. Dispersibility at the time of completion of stirring was visually observed and evaluated according to the following criteria. Results are shown in Table 7.

A: All of the solid particles are dispersed in the liquid, and precipitation does not occur in the bottom at all.

B: Though almost all of the solid particles are dispersed in the liquid, precipitation slightly occurs in the bottom.

C: About a half of the solid particles precipitate in the liquid.

D: Almost all of the solid particles precipitate in the bottom.

### <Test of Coating Film State>

To 10.0 parts of the dispersion after the dispersibility test, 0.4 parts of an acrylic resin (a trade name: “ACRYPET MD”, manufactured by Mitsubishi Rayon Co., Ltd.) was added and dissolved with stirring. The obtained mixed liquid was subjected to flow coating on a slide glass and dried in an oven at 120° C. for one hour. The obtained coating film was visually observed and evaluated according to the following criteria. Results are shown in Table 7.

A: The obtained coating film is transparent.

B: The obtained coating film is cloudy.

C: The solid particles aggregate, and the obtained coating film is not transparent.

TABLE 7

| | | Dispersant | | Fine powder | | Solvent | | | |
|---|---|---|---|---|---|---|---|---|---|
| | | | Ratio | | Ratio | | Ratio | | Coating |
| | | Type | (%) | Type | (%) | Type | (%) | Dispersibility | film state |
| Example | 3-1 | Production Example 3-7 | 1.2 | Pigment Blue 15:6 | 4.1 | PGMEA | 94.7 | A | A |
| | 3-2 | Production Example 3-8 | 1.2 | Pigment Blue 15:6 | 4.1 | PGMEA | 94.7 | A | A |
| | 3-3 | Production Example 3-9 | 1.2 | Pigment Blue 15:6 | 4.1 | PGMEA | 94.7 | A | A |
| | 3-4 | Production Example 3-10 | 1.2 | Pigment Blue 15:6 | 4.1 | PGMEA | 94.7 | A | A |
| | 3-5 | Production Example 3-11 | 1.2 | Pigment Blue 15:6 | 4.1 | PGMEA | 94.7 | A | A |
| | 3-6 | Production Example 3-12 | 1.2 | Pigment Blue 15:6 | 4.1 | PGMEA | 94.7 | A | A |
| | 3-7 | Production Example 3-13 | 1.2 | Pigment Blue 15:6 | 4.1 | PGMEA | 94.7 | A | A |
| | 3-8 | Production Example 3-14 | 1.2 | Pigment Blue 15:6 | 4.1 | PGMEA | 94.7 | A | A |
| | 3-9 | Production Example 3-15 | 1.2 | Pigment Blue 15:6 | 4.1 | PGMEA | 94.7 | A | A |
| | 3-10 | Production Example 3-16 | 1.2 | Pigment Blue 15:6 | 4.1 | PGMEA | 94.7 | A | A |
| | 3-11 | Production Example 3-17 | 1.2 | Pigment Blue 15:6 | 4.1 | PGMEA | 94.7 | A | A |
| | 3-12 | Production Example 3-18 | 1.2 | Pigment Blue 15:6 | 4.1 | PGMEA | 94.7 | A | A |
| | 3-13 | Production Example 3-19 | 1.2 | Pigment Blue 15:6 | 4.1 | PGMEA | 94.7 | A | A |
| | 3-14 | Production Example 3-20 | 1.2 | Pigment Blue 15:6 | 4.1 | PGMEA | 94.7 | A | A |
| | 3-15 | Production Example 3-21 | 1.2 | Pigment Blue 15:6 | 4.1 | PGMEA | 94.7 | A | A |
| | 3-16 | Production Example 3-22 | 1.2 | Pigment Blue 15:6 | 4.1 | PGMEA | 94.7 | A | A |
| | 3-17 | Production Example 3-23 | 1.2 | Pigment Blue 15:6 | 4.1 | PGMEA | 94.7 | A | A |
| | 3-18 | Production Example 3-24 | 1.2 | Pigment Blue 15:6 | 4.1 | PGMEA | 94.7 | A | A |
| | 3-19 | Production Example 3-25 | 1.2 | Pigment Blue 15:6 | 4.1 | PGMEA | 94.7 | A | A |
| | 3-20 | Production Example 3-7 | 1.2 | Pigment Blue 15:6 | 4.1 | Toluene | 94.7 | A | A |
| | 3-21 | Production Example 3-7 | 1.2 | Pigment Blue 15:6 | 4.1 | Butyl cellosolve | 94.7 | A | A |
| | 3-22 | Production Example 3-7 | 1.2 | Pigment Blue 15:6 | 4.1 | Methyl ethyl | 94.7 | A | A |
| | | | | | | ketone | | | |
| | 3-23 | Production Example 3-7 | 1.2 | Pigment Blue 15:6 | 4.1 | n-Hexane | 94.7 | A | A |
| | 3-24 | Production Example 3-7 | 1.2 | Pigment Red 177 | 4.1 | PGMEA | 94.7 | A | A |
| | 3-25 | Production Example 3-7 | 1.2 | Pigment Red 254 | 4.1 | PGMEA | 94.7 | A | A |
| | 3-26 | Production Example 3-7 | 1.2 | Zirconia | 4.1 | PGMEA | 94.7 | A | A |
| | 3-27 | Production Example 3-7 | 1.2 | Magnesium oxide | 4.1 | PGMEA | 94.7 | A | A |
| | 3-28 | Production Example 3-7 | 1.2 | Talc | 4.1 | PGMEA | 94.7 | A | A |
| | 3-29 | Production Example 3-7 | 1.2 | Potassium carbonate | 4.1 | PGMEA | 94.7 | A | A |
| Comparative | 3-1 | Production Example 1-1 | 1.2 | Pigment Blue 15:6 | 4.1 | PGMEA | 94.7 | D | C |
| Example | 3-2 | Comparative Production | 1.2 | Pigment Blue 15:6 | 4.1 | PGMEA | 94.7 | B | B |
| | | Example 1-1 | | | | | | | |
| | 3-3 | Dispersant *¹ | 1.2 | Pigment Blue 15:6 | 4.1 | PGMEA | 94.7 | A | A |
| | 3-4 | Dispersant *² | 1.2 | Pigment Blue 15:6 | 4.1 | PGMEA | 94.7 | C | C |

PGMEA: Propylene glycol monomethyl ether acetate

### INDUSTRIAL APPLICABILITY

In dispersing solid particles in a nonaqueous liquid in the fields of paints, printing inks, toners for electrostatic copying, plastics, pigment printing agents, inks for inkjet printing, inks for thermal transfer recording, resists for color filter, inks for writing, etc., the dispersant of the invention prevents aggregation of the solid particles in a dispersion liquid from occurring and is extremely effective for forming a stable dispersion liquid.

1. A polyvinyl acetal/polyester graft copolymer, which is obtained by allowing a polyvinyl acetal having one or more of each of constituent units represented by the following general formulae (1) to (3) and having a weight average molecular weight of from 100 to 100,000 and a polyester having at least one carboxyl group at an end of a main chain thereof and having a weight average molecular weight of from 100 to 50,000 to react with each other, wherein
from 1 to 95% by mole of a hydroxyl group which the polyvinyl acetal has forms a graft bond with the polyester: 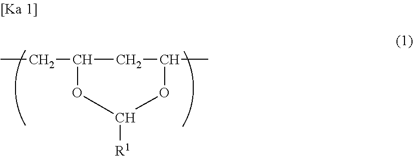
wherein R¹ represents a hydrogen atom, a linear or branched alkyl group having a carbon number of from 1 to 20, or an aryl group, in which the alkyl group or the aryl group may have a substituent, and 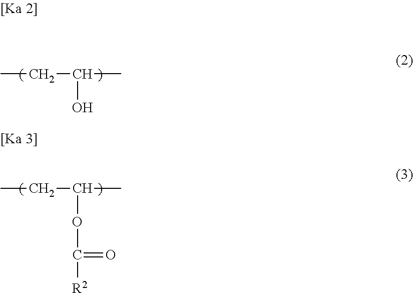
wherein R² represents a hydrogen atom, a linear or branched alkyl group having a carbon number of from 1 to 20, or an aryl group, in which the alkyl group or the aryl group may have a substituent.

2. A polyvinyl acetal/polyester graft copolymer, which is obtained subjecting a polyvinyl acetal having one or more of each of constituent units represented by the following general formulae (1) to (3) and having a weight average molecular weight of from 100 to 100,000 to addition polymerization with a lactone in an amount of from 1 to 50 molar equivalents to a hydroxyl group which this polyvinyl acetal has: 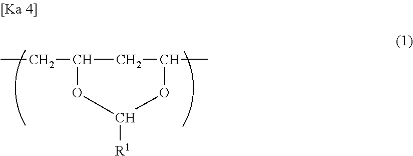
wherein R¹ represents a hydrogen atom, a linear or branched alkyl group having a carbon number of from 1 to 20, or an aryl group, in which the alkyl group or the aryl group may have a substituent, and 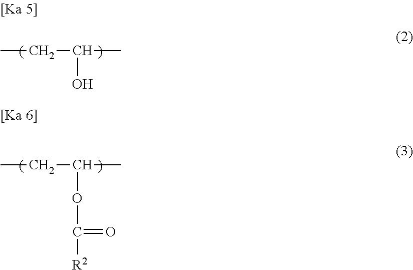
wherein R² represents a hydrogen atom, a linear or branched alkyl group having a carbon number of from 1 to 20, or an aryl group, in which the alkyl group or the aryl group may have a substituent.

3. A polyvinyl acetal/polyester graft copolymer, which is obtained by allowing a polyvinyl acetal having one or more of each of constituent units represented by the following general formulae (1) to (3) and having a weight average molecular weight of from 100 to 100,000 and a polyester having a weight average molecular weight of from 100 to 50,000 to react with each other, wherein
from 1 to 95% by mole of a hydroxyl group which the polyvinyl acetal has forms a bond by an ester exchange reaction with the polyester: 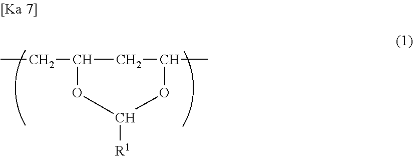
wherein R¹ represents a hydrogen atom, a linear or branched alkyl group having a carbon number of from 1 to 20, or an aryl group, in which the alkyl group or the aryl group may have a substituent, and 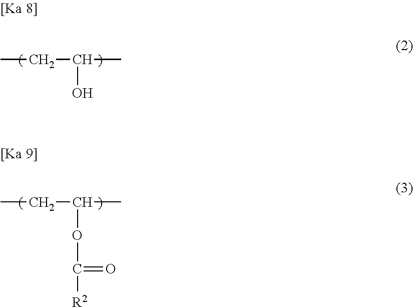
wherein R² represents a hydrogen atom, a linear or branched alkyl group having a carbon number of from 1 to 20, or an aryl group, in which the alkyl group or the aryl group may have a substituent.

4. A dispersant containing the polyvinyl acetal/polyester graft copolymer according to any one of claims 1 to 3.

5. A solid particle dispersion having solid particles dispersed in a nonaqueous liquid by the dispersant according to claim 4.
